(19) United States
(12) Patent Application Publication
(10) Pub. No.: US 2024/0413067 A1
(43) Pub. Date: Dec. 12, 2024

(54) ELECTRONIC PACKAGE MODULE AND METHOD FOR FABRICATION OF THE SAME

(71) Applicant: Unimicron Technology Corp., Taoyuan (TW)

(72) Inventors: Chia-Yu PENG, Taoyuan (TW); Kai-Ming YANG, Hsinchu County (TW); Pu-Ju LIN, Hsinchu City (TW); Cheng-Ta KO, Taipei City (TW)

(21) Appl. No.: 18/360,826

(22) Filed: Jul. 28, 2023

(30) Foreign Application Priority Data
Jun. 9, 2023 (TW) 112121734

(51) Int. Cl. H01L 23/498; H01L 21/48; H01L 21/56; H01L 23/00; H01L 23/13; H01L 23/31

(52) U.S. Cl. CPC H01L 23/49822; H01L 21/4857; H01L 21/568; H01L 23/13; H01L 23/3121; H01L 24/13; H01L 24/16; H01L 24/48; H01L 2224/13147; H01L 2224/16237; H01L 2224/48091; H01L 2224/48105; H01L 2224/48228

(57) ABSTRACT

An electronic package module including a circuit substrate, an electronic component disposed on the circuit substrate and a molding compound is provided. The molding compound encapsulates the circuit substrate and the electronic component. The circuit substrate includes a first circuit layer and a first insulation layer covering on the first circuit layer. The first insulation layer has a boundary surface where a second circuit layer is disposed. A second insulation layer covers a part of the second circuit layer while the insulation layer bares a region surrounding the perimeter of the boundary surface. The molding compound directly contacts the region and the second insulation layer.

### RELATED APPLICATIONS

This application claims priority to Taiwan Application Serial Number 112121734, filed Jun. 9, 2023, which is herein incorporated by reference in its entirety.

### BACKGROUND

### Technical field

The present disclosure relates to an electronic package module. More particular, the present disclosure relates to the electronic package module with redistribution layer (RDL).

### Description of Related Art

In the trend of developing thinner and lighter electronic equipment, increasing the quantity of signal input and output (I/O) component in a limited space is necessary. Thus, the packaging technology of redistribution layer (RDL) has been developed. However, the RDL substrate, especially the ultra-thin RDL substrate is prone to damage during the singulation process, for example, cracks are prone to be formed at the edge of the cutting surface.

Furthermore, adhesion between ultra-thin RDL substrates and the molding compounds are weak, so that the structural strength of the packaging module is insufficient. The reasons above influence the yield loss of the RDL packaging, thereby reducing the reliability of the electronic products using the RDL technology.

### SUMMARY

Accordingly, the disclosure is to provide a method for improving yield of electronic package modules and to provide the electronic package module fabricated by this method.

At least one embodiment of the disclosure provides an electronic package module including the circuit substrate with the first circuit layer. The circuit substrate includes the first insulation layer covering the first circuit layer and having the first boundary surface. The second circuit layer is located on the first boundary surface of the first insulation layer and electrically is connected to the first circuit layer. The second insulation layer is located on the first boundary surface and partially covers the second circuit layer. The second insulation layer bares the first region of the first boundary surface, and the first region is located on a perimeter of the first boundary surface. The electronic component is located on the circuit substrate and is electrically connected to the circuit substrate. The molding compound encapsulates the circuit substrate and the electronic component, while the molding compound directly touches the first region of the first boundary surface and the second insulation layer.

At least in one embodiment of the disclosure, the second insulation layer further includes the plurality of trenches. The molding compound directly touches inner surfaces of the plurality of trenches, and the plurality of trenches and the first region of the first boundary surface are not overlapping.

At least in one embodiment of the disclosure, the inner surfaces of the plurality of trenches include a part of the first boundary surface.

At least in one embodiment of the disclosure, the electronic component overlaps the second region of the first boundary surface surrounded by the first region. At least one of the plurality of trenches is located between the second region and the first region.

At least in one embodiment of the disclosure, the electronic component covers at least one of the plurality of trenches.

At least in one embodiment of the disclosure, the electronic component covers none of the plurality of trenches.

At least in one embodiment of the disclosure, the electronic package module further includes the plurality of soldering materials electrically connecting the electronic component with the second circuit layer. The plurality of soldering materials overlaps the plurality of third regions surrounded by the first region. At least one of the plurality of trenches is located between two of the plurality of third regions adjacent to each other.

At least in one embodiment of the disclosure, the electrical package module further includes the third circuit layer located on the second boundary surface of the second insulation layer and electrically connected to the second circuit layer. The first boundary surface and the second boundary surface are located on two opposite sides of the second insulation layer separately. The third insulation layer is located on the second boundary surface and partially covers the third circuit layer, and the third insulation layer bares the second region of the second boundary surface. The second region which the molding compound directly touches is located on the perimeter of the second boundary surface.

At least in one embodiment of the disclosure, the molding compound covers the side wall of the first insulation layer.

At least one embodiment of the disclosure provides a method for fabricating an electronic package module. The method includes providing the provisional carrier; forming the circuit substrate on the provisional carrier and baring the surface of the provisional carrier; disposing the electronic component on the circuit substrate and electrically connecting the electronic component with the circuit substrate; disposing the molding compound on the provisional carrier, and the circuit substrate and the electronic component are encapsulated by the molding compound which covers the surface of the provisional carrier; removing the provisional carrier after disposing the molding compound; and cutting the molding compound after removing the provisional carrier. The circuit substrate comprises the recessed region surrounding the side wall of the circuit substrate, and the recessed region is filled up with the molding compound.

At least in one embodiment of the disclosure, forming the circuit substrate on the provisional carrier includes forming the first circuit layer on the provisional carrier; disposing the first insulation material on the first circuit layer, so that the first insulation material covers the provisional carrier and the first circuit layer; patterning the first insulation material to form a first insulation layer, and the first insulation layer bares the surface of the provisional carrier; forming the second circuit layer on the first circuit layer, while the second circuit layer is electrically connected to the first circuit layer; disposing the second insulation material on the second circuit layer, so that the second insulation material covers the first insulation layer and the second circuit layer; patterning the second insulation material to form a second insulation layer, and the boundary surface of the first insulation layer is located between the first insulation layer and the second insulation layer. The second insulation layer bares the region of the boundary surface, and thus the recessed region of the circuit substrate is formed.

At least in one embodiment of the disclosure, the side wall of the circuit substrate is the side wall of the second insulation layer, and the side wall is surrounded by the recessed region.

At least in one embodiment of the disclosure, the method further includes forming a surface treatment layer on the first circuit layer after removing the provisional carrier.

A least in one embodiment of the disclosure, the method further includes forming a surface treatment layer on the first circuit layer after cutting the molding compound.

At least in one embodiment of the disclosure, the method further includes electrically connecting the electronic component with the second circuit layer through the plurality of soldering materials. The second insulation layer bares the part of the boundary surface, and thus the plurality of trenches spaced from the plurality of soldering materials and the recessed region are formed.

According to the aforementioned embodiments, the molding compound covers the side wall of the circuit substrate. Thus, the molding compound can protect the side wall of the circuit substrate during the singulation process. As a result, the circuit substrate is prevented from the damages formed by direct touch of the cutting device, thereby improving the yield loss of the electronic package module.

### BRIEF DESCRIPTION OF THE DRAWINGS

To illustrate more clearly the aforementioned and the other features, merits, and embodiments of the present disclosure, the description of the accompanying figures are as follows:

FIG. 1A illustrates a cross-sectional view of an electronic package module in accordance with one embodiment of the present disclosure.

FIG. 1B illustrates a locally top view of an electronic package module in accordance with the embodiment of FIG. 1A.

FIG. 2A illustrates a cross-sectional view of an electronic package module in accordance with another embodiment of the present disclosure.

FIG. 2B illustrates a locally top view of an electronic package module in accordance with the embodiment of FIG. 2A.

FIG. 3A illustrates a cross-sectional view of an electronic package module in accordance with another embodiment of the present disclosure.

FIG. 3B illustrates a locally top view of an electronic package module in accordance with the embodiment of FIG. 3A.

FIG. 4 illustrates a cross-sectional view of an electronic package module in accordance with another embodiment of the present disclosure.

FIG. 5A to FIG. 5H illustrate cross-sectional views of a method for fabricating an electronic package module in accordance with one embodiment of the present disclosure.

### DETAILED DESCRIPTION

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/−30%, +/−20%, +/−10% or +/−5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

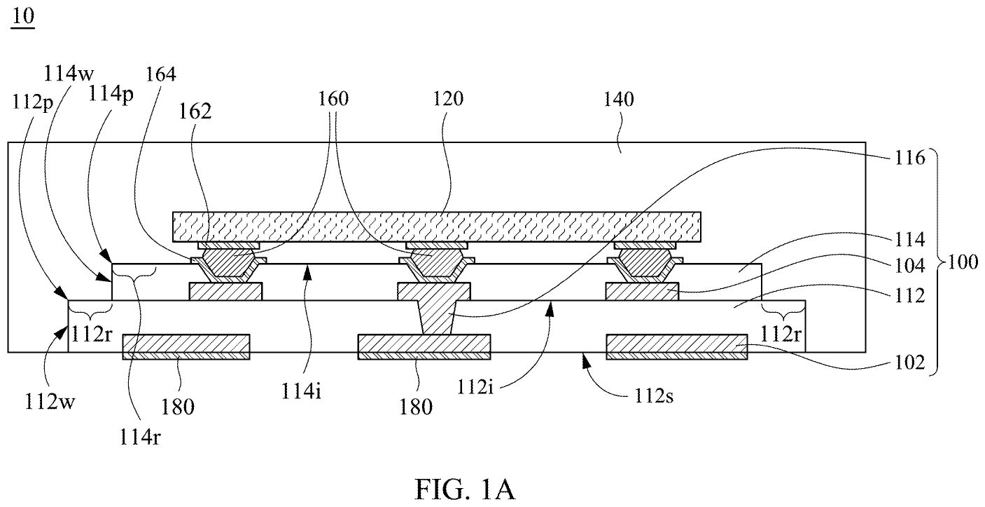

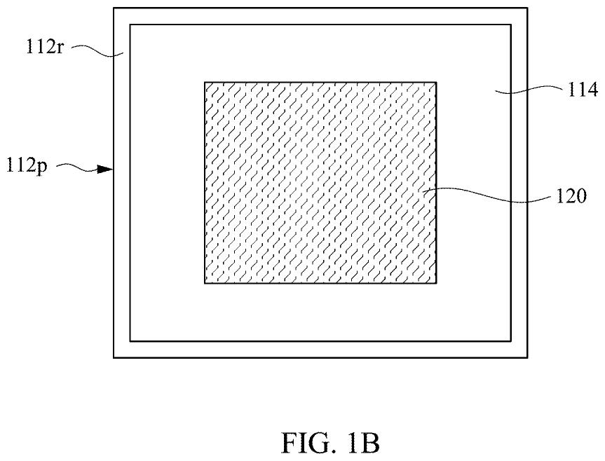

Referring to FIG. 1A, the structure of the electronic package module in at least one embodiment is disclosed. The electronic package module 10 of this embodiment includes the circuit substrate 100, the electronic component 120 and the molding compound 140. In the embodiment, the circuit substrate 100 which is a substantial RDL includes the circuit layer 102, the circuit layer 104, the insulation layer 112, the insulation layer 114 and the conductive via 116. As shown in FIG. 1A, the insulation layer 112 covers the circuit layer 102, and the insulation layer 112 has the boundary surface 112i and the surface 112s opposite to the boundary surface 112i.

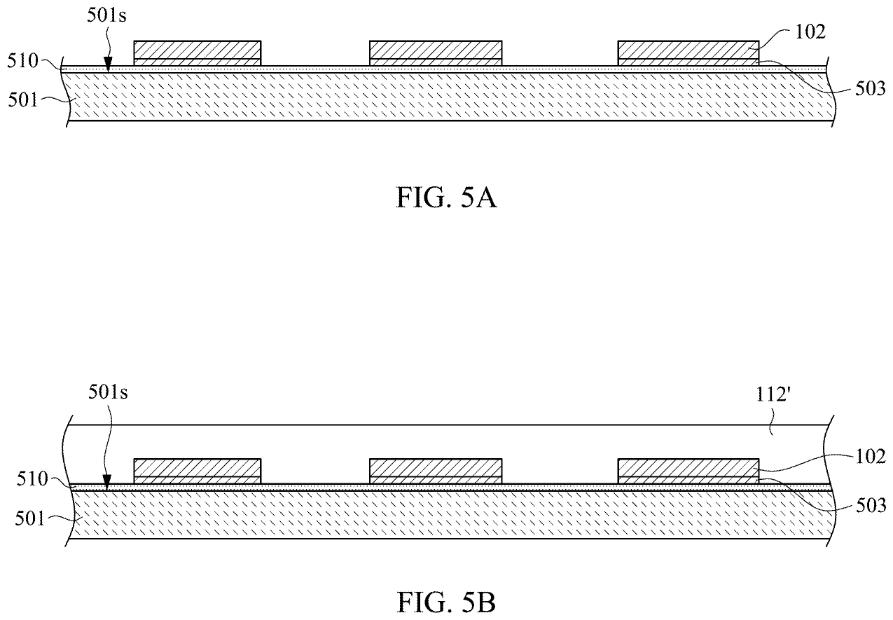

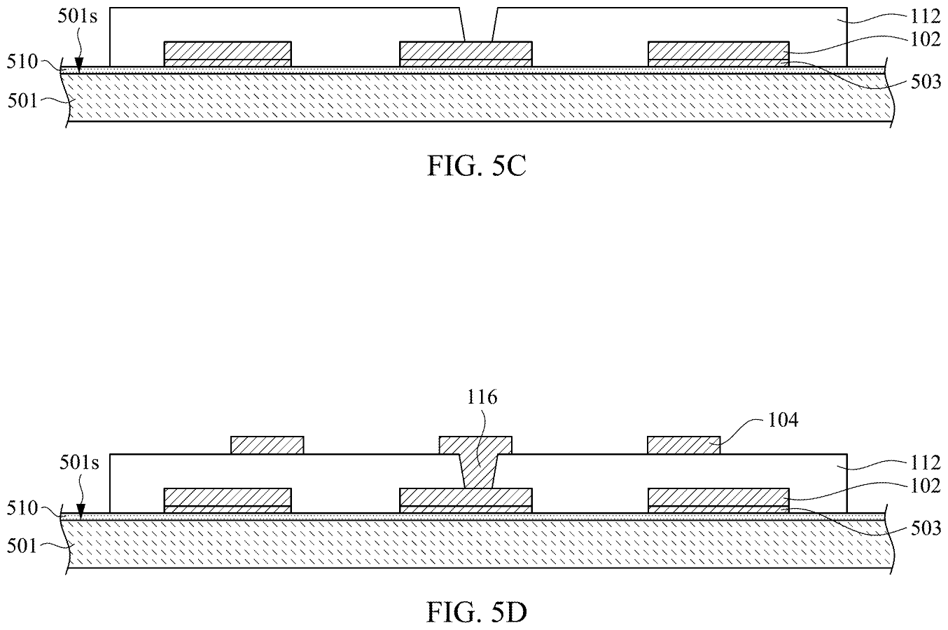

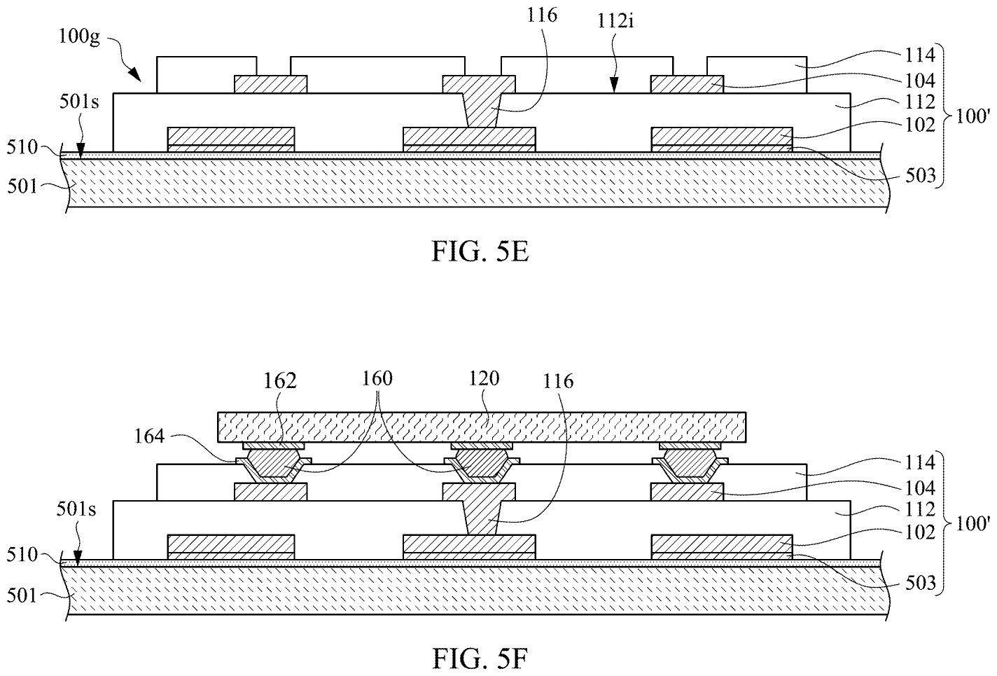

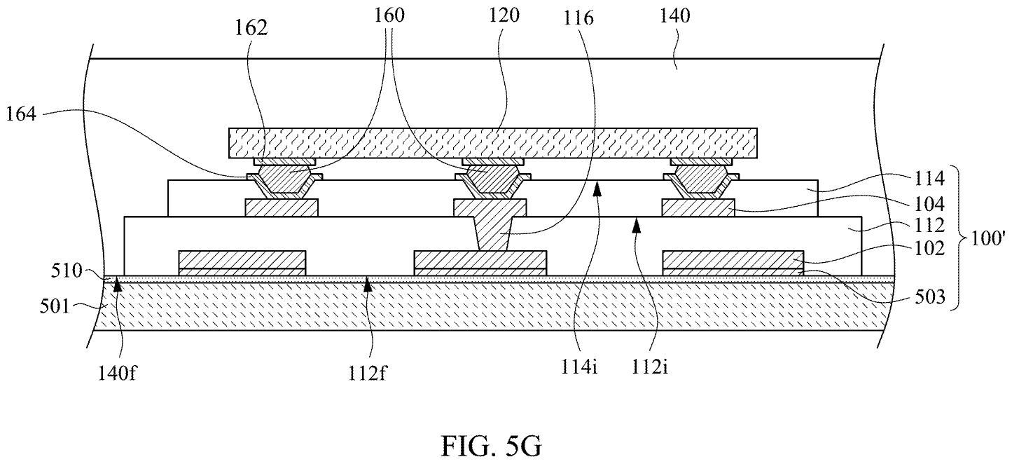

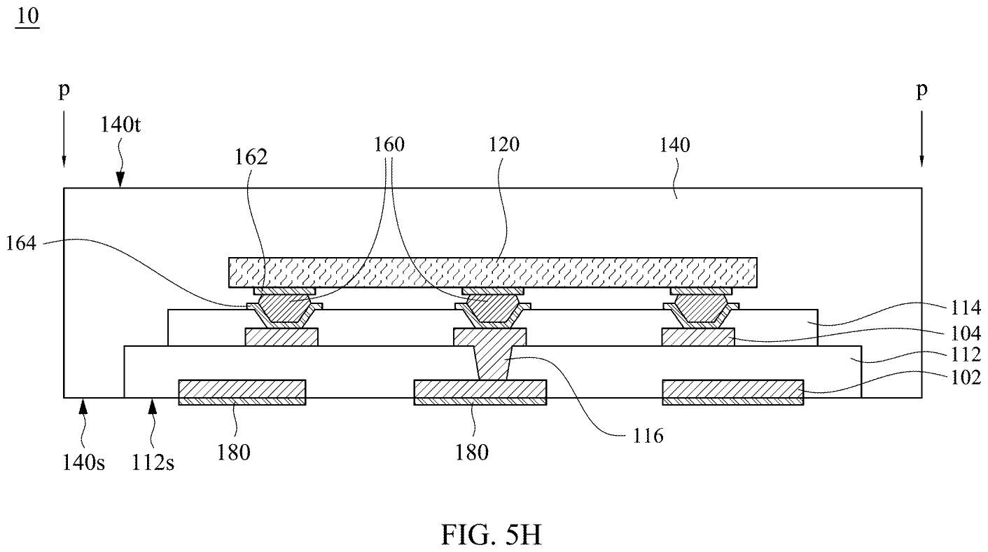

It is noteworthy that the insulation layer 112 covers one surface (not shown) of the circuit layer 102 but the other surface (not shown) of the circuit layer 102. The surface not covered by the insulation layer 112 is aligned with the surface 112s of the insulation layer 112, that is, one surface of the circuit layer 102 and the 122s of the insulation layer 112 are coplanar. Further, one surface of the molding compound 140 (i.e., the surface 140s in FIG. 5H), the surface 112s and one surface of the circuit layer 102 are coplanar.

The circuit layer 104 is located on the boundary surface 112i of the insulation layer 112 and is electrically connected to the circuit layer 102 through the conductive via 116 located between the circuit layer 102 and the circuit layer 104. The disclosure is not limited to the embodiment that only one conductive via 116 is illustrated. The quantity of the conductive via 116 depending on the circuit layout may be one or above.

The insulation layer 114 is located on the boundary surface 112i of the insulation layer 112 and partially covers the circuit layer 104. In particular, the plurality of pads 164 are located on the circuit layer 104 and directly touch a part of the circuit layer 104 as shown in FIG. 1A. The part of the circuit layer 104 where the plurality of pads 164 directly touch is not covered by the insulation layer 114.

FIG. 1B illustrates the locally top view of the electronic package module 10, while the molding compound 140 is omitted. Referring to FIG. 1A and FIG. 1B, the insulation layer 114 bares the region 112r of the boundary surface 112i, and the region 112r is located on the perimeter 112p of the boundary surface 112i. As shown in FIG. 1B, the region 112r surrounds the insulation layer 114 and is formed to be a closed rectangle, but the disclosure is not limited to this embodiment. That is, the region 112r may discontinuously surround the insulation layer 114 and be formed to be a disclosed rectangle.

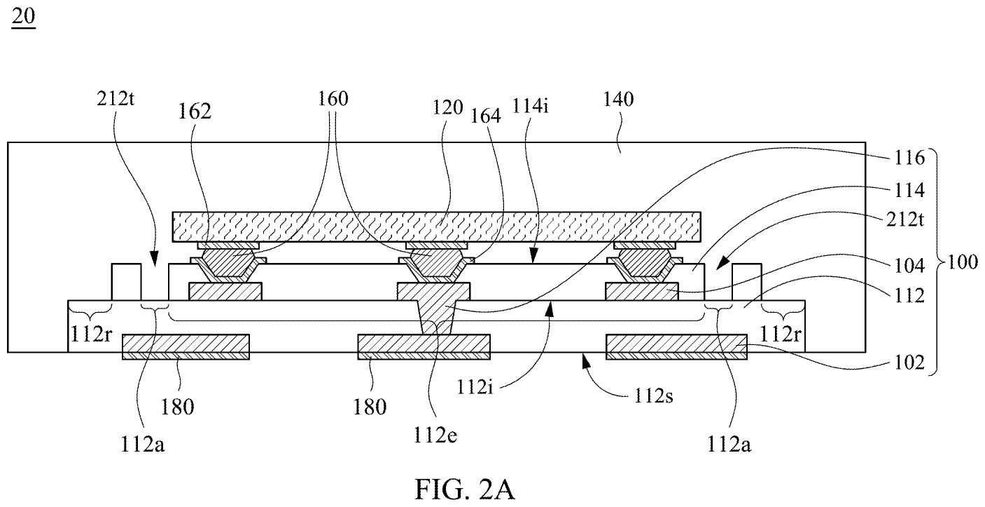

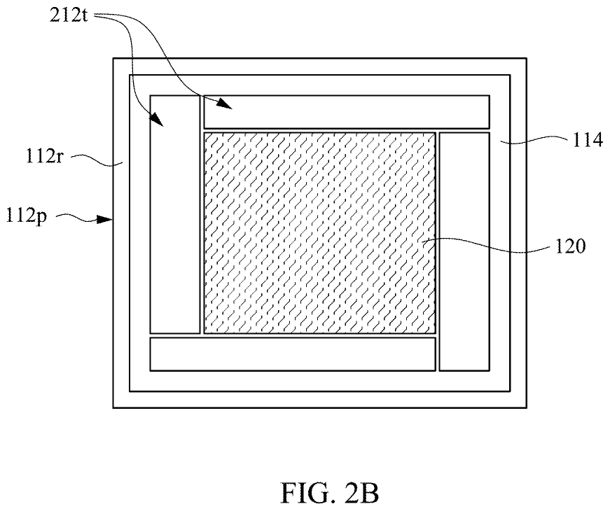

Referring to FIG. 2A illustrating the electronic package module 20 of another embodiment. The electronic package module 20 is similar to the electronic package module 10, while the difference between two electronic package modules is that the insulation layer 114 of the electronic package module 20 further includes the plurality of trenches 212t. The plurality of trenches 212t are located on the boundary surface 112i, more specifically, the inner surfaces of the plurality of trenches 212t include the part 112a (i.e., the bottoms of the plurality of trenches 212t shown in FIG. 2A) of the boundary surface 112i.

FIG. 2B illustrates the locally top view of the aforementioned embodiment, while the molding compound 140 is omitted. Referring to FIG. 2A and FIG. 2B, the plurality of trenches 212t and the region 112r of the boundary surface 112i are not overlapping. In other words, the plurality of trenches 212t of the insulation layer 114 is spaced from the region 112r. In addition, the electronic component 120 overlaps the region 112e of the boundary surface 112i. In other words, the region 112e is the area of the boundary surface 112i covered by the electronic component 120. As shown in FIG. 2A, the region 112e is surrounded by the region 112r and the plurality of trenches 212t are located between the region 112r and the region 112e.

In this embodiment, four trenches 212t are located between the region 112r and the electronic component 120 and surround the electronic component 120 separately. However, the shapes, quantities and locations of the plurality of trenches 212t are not limited to this embodiment. In other embodiments, the quantity of the plurality of trenches 212t may be one or above, and the plurality of trenches 212t may surround the electronic component 120 and be formed to be a closed rectangle.

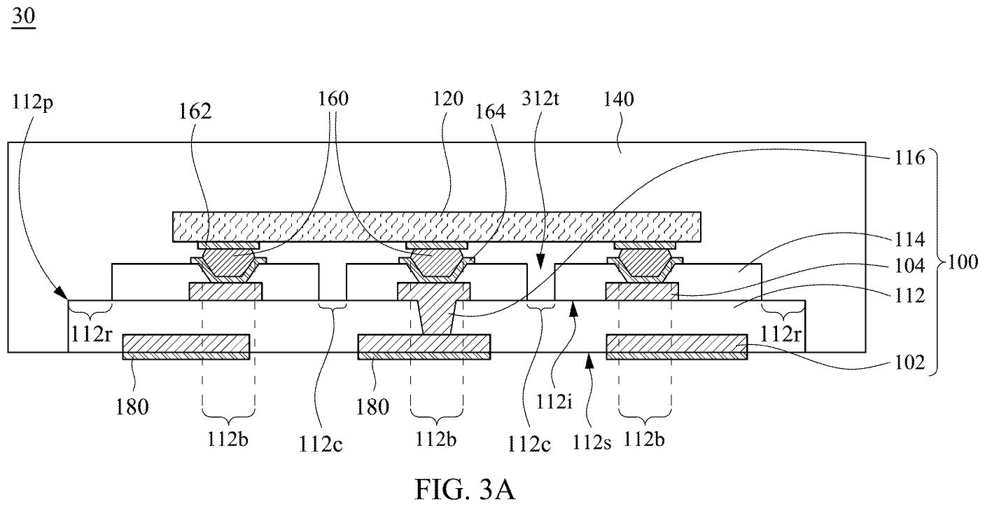

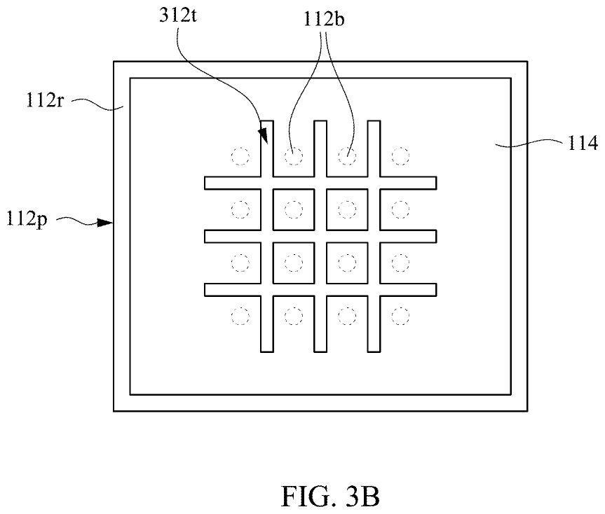

Referring to FIG. 3A illustrating the electronic package module 30 of another embodiment. The electronic package module 30 is similar to the electronic package module 10, while the difference between two electronic package modules is that the insulation layer 114 of the electronic package module 30 further includes the plurality of trenches 312t, and the plurality of trenches 312t are located on the boundary surface 112i. As shown in FIG. 3A, the electronic component 120 covers the plurality of trenches 312t. In other words, the electronic component 120 and the plurality of trenches 312t are overlapping in the normal direction.

The electronic package module 30 further includes the plurality of soldering materials 160 which connect the electronic component 120 and the circuit layer 104. It is worth mentioning, the electronic component 120 is located on and electrically connected to the circuit substrate 100 in each aforementioned embodiment. Each of the plurality of soldering materials 160 is electrically connected to the electronic component 120 through the pad 162 and is electrically connected to the circuit layer 104 through one of the plurality of pads 164. In this embodiment, the plurality of soldering materials 160 and the plurality of regions 112b of the boundary surface 112i are overlapping. The plurality of soldering materials 160 may be solder balls, copper pillars or other connecting structures for electrical connection.

FIG. 3B illustrates the locally top view of the electronic package module 30, while the electronic component 120 (including the pad 162 on the electronic component 120) and the molding compound 140 is omitted. Referring to FIG. 3A and FIG. 3B, the region 112r surrounds the plurality of regions 112b of the boundary surface 112i where the plurality of soldering materials 160 overlap. In this embodiment, one of the plurality of trenches 312t is located between two of the plurality of regions 112b adjacent to each other. More specifically, the plurality of trenches 312t are spaced from the region 112r of the boundary surface 112i and may be formed to be a grid (as shown in FIG. 3B). Each of the plurality of regions 112b is located in one cell of the grid formed of the plurality of trenches 312t. In other words, some parts of the plurality of trenches 312t are located between two of the plurality of soldering materials 160 (i.e., two of the plurality of regions 112b). Furthermore, the inner surfaces of the plurality of trenches 312t include the plurality of parts 112c of the boundary surface 112i (i.e., the bottoms of the plurality of trenches 312t in FIG. 3A).

In other embodiments, the electronic package module may include the plurality of trenches 212t and the plurality of 313t of the aforementioned embodiments. For example, the plurality of trenches 212t is located between the region 112r and the region 112e, and the plurality of trenches 312t are located between two of the plurality of regions 112b adjacent to each other.

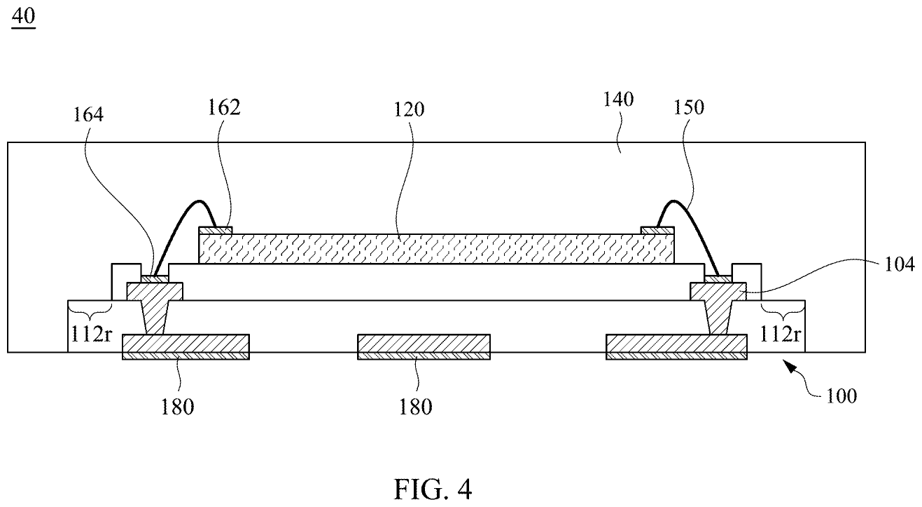

In addition, referring to FIG. 4, the electronic component 120 may be electrically connected to the circuit substrate 100 with the method of wire-bonding in other embodiments. In particular, the electronic component 120 of the electronic package module 40 is electrically connected to the circuit substrate 100 through the metal wire 150. Two ends of the 150 are connected to the pad 162 of the electronic component 120 and one of the plurality of pads 164 of the circuit layer 104.

As shown in FIG. 1A, the molding compound 140 included in the electronic package module (e. g., the electronic package module 10) encapsulates the circuit substrate 100 and the electronic component 120. In various embodiments of the disclosure, the molding compound 140 directly touches the region 112r of the boundary surface 112i and the insulation layer 114. The molding compound 140 may include insulation materials, such as organic resin (e.g., Epoxy resin or Acrylonitrile butadiene styrene) or similarity thereof. Besides, the molding compound 140 covers and directly touches the side wall 112w of the insulation layer 112.

It is noteworthy that the molding compound 140 directly touches the inner surfaces of the plurality of trenches 212t in the electronic package module 20. More specifically, the plurality of trenches 212t is filled up with the molding compound 140 entirely. One the other hand, the molding compound 140 directly touches the inner surfaces of the plurality of trenches 312t in the electronic package module 30, while the plurality of trenches 312t are filled up with the molding compound 140 entirely. As a result, the contact area between the molding compound 140 and the circuit substrate 100 are increased, thereby enhancing the adhesion between the molding compound 140 and the circuit substrate 100.

Although two circuit layers (i.e., the circuit layer 102 and the circuit layer 104) and two insulation layers (i.e., the insulation layer 112 and the insulation layer 114) are disposed in the circuit substrate 100 respectively, they are not limited to aforementioned embodiments. That is, each quantity of the circuit layers and the insulation layers may be two or above (e.g., three). For instance, in other embodiments as shown in FIG. 1A, the electronic package module 10 may further include a circuit layer (not shown) located on the boundary surface 114i of the insulation layer 114, and this circuit layer is electrically connected to the circuit layer 104. The boundary surface 112i and the boundary surface 114i are on two opposite sides of the insulation layer 114 separately.

Moreover, the electronic package module 10 may further include a insulation layer (not shown) located on the boundary surface 114i of the insulation layer 114, and this insulation layer partially covers the circuit layer (not shown) on the boundary surface 114i. This insulation layer bares the region 114r of the boundary surface 114i, while the region 114r is located on the perimeter 114p of the boundary surface 114i. It is noteworthy that the molding compound 140 directly touches the region 114r of the boundary surface 114i in the embodiments which have three or more insulation layers.

Referring to FIG. 1A, although the angle between the region 112r and the side wall 114w of the insulation layer 114 is a right angle, the disclosure is not limited to this embodiment. In other embodiments, the angle between the region 112r and the side wall 114w of the insulation layer 114 may be a non-right angle, such as a fillet corner.

As shown in FIG. 1A, the electronic package module 10 may further include the surface treatment layer 180. The surface treatment layer 180 is located on the surface 112s of the insulation layer 112 and protrudes the surface 112s. In some embodiments, the circuit substrate 100 may further include at least one solder mask (not shown) which covers the boundary surface 114i of the insulation layer 114 and bares the pad 162. In addition, the solder mask may further cover the surface 112s of the insulation layer 112 and bare the surface treatment layer 180.

Although each of the aforementioned embodiments illustrates only one electronic component 120, the disclosure is not limited to those embodiments. The quantity of the electronic component 120 may be one or above (e.g., two). Furthermore, the electronic component 120 may be a chip or a die.

A method for fabrication of the electronic package module includes sequent steps illustrated in FIG. 5A to FIG. 5H, while the method is in accordance with the electronic package module 10 shown in FIG. 1A. In the embodiment, firstly, the provisional carrier 501 is provided. The material of the provisional carrier 501 may include glass or polymers material (e.g., polyethylene terephthalate). It is worth mentioning, the release layer 510 which may include release materials (e.g., silicone release agents) is disposed on the provisional carrier 501, but the disclosure is not limited to this embodiment. In other embodiments, the release layer 510 may be excluded.

Afterwards, the circuit substrate 100′ is formed on the provisional carrier 501, and the surface 501s of the provisional carrier 501 is bared. It is noteworthy that since the release layer 510 is disposed in this embodiment, the circuit substrate 100′ is formed on the release layer 510, so that the surface 140s of the provisional carrier 501 is covered by the release layer 510 instead of being exposed. However, since other embodiments may exclude the release layer 510, the provisional carrier 501 is depicted as being bared on the premise that the release layer 510 is omitted.

The step is illustrated in details as following. First, the seed layer 503 is deposited on the provisional carrier 501 (or on the release layer 510) by sputtering or similarity thereof. In this embodiment, the seed layer 503 may include metal materials, such as copper or similarity thereof. Second, the photoresist material (not shown) is deposited on the seed layer 503, and then the photoresist material is patterned to bare a part of the seed layer 503 by photolithography, laser direct imaging (LDI) or similarity thereof.

Afterwards, copper is deposited on the bared part of the seed layer 503 by electroplating, electroless plating or similarity thereof. The photoresist material is removed by stripping after the seed layer 503 is plating by copper, and the part of the seed layer 503 covered by the photoresist material is removed by etching. Thus, the step of forming the circuit layer 102 on the surface 140s of the provisional carrier 501 illustrated in FIG. 5A is completed. Referring to FIG. 5B, forming the circuit substrate 100′ (denoted in FIG. 5B) includes the insulation material 112′ is disposed on the circuit layer 102 to cover the provisional carrier 501 and the circuit layer 102. The insulation material 112′ may include organic resin (such as epoxy resin) or other insulation material, or similarity thereof.

Referring to FIG. 5C, the insulation material 112′ is patterned as the insulation layer 112 by LDI or similarity thereof after the insulation material 112′ is disposed. Furthermore, the insulation layer 112 bares the surface 140s of the provisional carrier 501, and the surface 140s is located between the provisional carrier 501 and the insulation layer 112 of the circuit substrate 100′ (denoted in FIG. 5C).

Next, referring to FIG. 5D, the circuit layer 104 is formed on the insulation layer 112. The step of forming the circuit layer 104 is similar to the aforementioned step of forming the circuit layer 102, thus, the descriptions of this step is not repeated hereof. It is worth mentioning, the step of forming the circuit layer 102 on the insulation layer 112 includes forming the conductive via 116, so that the circuit layer 104 could be electrically connected to the circuit layer 102.

After forming the circuit layer 102, another insulation material (not shown) is disposed on the circuit layer 102, so that this insulation material covers the insulation layer 112 and the circuit layer 102. The insulation material may include organic resin (such as epoxy resin) or other insulation material, or similarity thereof. Referring to FIG. 5E, the insulation material is patterned as the insulation layer 114 afterwards.

As shown in FIG. 5E, the boundary surface 112i of the insulation layer 112 is located between the insulation layer 112 and the insulation layer 114. After the patterning process, the insulation layer 114 bares the region 112r of the boundary surface 112i, and then the recessed region 100g of the circuit substrate 100′ is formed. More specifically, the circuit substrate 100′ includes the recessed region 100g, and partial of the side wall located on one side of the insulation layer 114 is surrounded by the recessed region 100g. Thus, the step of forming the circuit substrate 100′ on the provisional carrier 501 (and the release layer 510) and baring the surface 140s of the provisional carrier 501 is completed.

Referring to FIG. 5F, the electronic component 120 is disposed on the circuit substrate 100′, and the electronic component 120 is electrically connected to the circuit layer 104 through the plurality of soldering materials 160 after the circuit substrate 100′ is formed. Two sides of each of the plurality of soldering materials 160 are separately connected to the pad 162 on the electronic component 120 and one of the plurality of pads 164 on the circuit layer 104, so that the electronic component 120 is electrically connected to the circuit substrate 100′. Although FIG. 5F depicts only one electronic component 120, the quantity of the electronic component 120 is not limited to this embodiment. One and above electronic component 120 may be disposed on the circuit substrate 100′.

As shown in FIG. 5G, after the electronic component 120 is disposed, the molding compound 140 is disposed on the provisional carrier 501 (or on the release layer 510), and the circuit substrate 100′ and the electronic component 120 are encapsulated by the molding compound 140. It is noteworthy that the molding compound 140 covers the surface 140s of the provisional carrier 501, and the recessed region 100g of the circuit substrate 100′ is filled up with the molding compound 140. More specifically, the molding compound 140 covers the side wall (denoted) of the circuit substrate 100′, the partial boundary surface 112i of the insulation layer 112 and the partial boundary surface 114i of the insulation layer 114. After the molding compound 140 is disposed, the provisional carrier 501 is removed and bares the initial surface 112f of the insulation layer 112 and the initial surface 140f of the molding compound 140. Moreover, the provisional carrier 501 may be removed by laser ablation.

Referring to FIG. 5H, the surface treatment layer 180 is formed on the circuit layer 102 after the release layer 510 and the provisional carrier 501 are removed. The surface treatment layer 180 may be formed by hot air solder leveling (HASL), organic soldering preservative, electroless nickel immersion gold (ENIG), immersion silver or electroplating gold to prevent the circuit layer 102 from oxidation. Furthermore, in this embodiment, the seed layer 503 and the partial insulation layer 112 and the partial molding compound 140 may be removed by etching after the release layer 510 and the provisional carrier 501 are removed but before the surface treatment layer 180 is formed. Thus, the circuit layer 102, surface 112s of the insulation layer 112 and the surface 140s of the molding compound 140 are bared.

Afterwards, the molding compound 140 is cut by machine cutting, laser cutting, focus ion beam cutting or similarity thereof. As shown in FIG. 5H, the cutting device p cuts the molding compound 140 from the surface 140t and along with the normal of the surface 140s, so that the plurality of electronic package elements 10 is formed. The cutting device p in FIG. 5H may represent a cutter, a laser beams or an ion beam. Although the surface treatment layer 180 is disposed before the cutting process, the disclosure is not limited to the embodiment. The surface treatment layer 180 may be disposed after the cutting process.

Another embodiment is to form the electronic package module 20. In this embodiment, the insulation layer 114 bares another part of the boundary surface 112i through the step of patterning the insulation layer 114, and thus the plurality of trenches 212t are formed. The plurality of trenches 212t are spaced from the plurality of soldering materials 160 and the recessed region 100g of the circuit substrate 100′.

In conclusion, the molding compound covers the side wall of the circuit substrate before the cutting process is conducted to form the electronic package module. As a result, the cutting device cuts the molding compound without touching the circuit substrate, so that the circuit substrate is prevented from the damages, such as cracks, during cutting process, thereby improving the yield loss of the electronic package module during cutting process. In addition, the present of the recessed region and the trenches increases the contact area between the molding compound and the circuit substrate. Therefore, the adhesion between the molding compound and the circuit substrate is enhanced to break the limitation of minimum standoff adhesion, thereby increasing the structural stability of the electronic package module.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. An electronic package module, comprising:
a circuit substrate comprising:
a first circuit layer;
a first insulation layer covering the first circuit layer and having a first boundary surface;
a second circuit layer located on the first boundary surface of the first insulation layer and electrically connected to the first circuit layer; and
a second insulation layer located on the first boundary surface and partially covering the second circuit layer, wherein the second insulation layer bares a first region of the first boundary surface, and the first region is located on a perimeter of the first boundary surface;
an electronic component located on the circuit substrate and electrically connected to the circuit substrate; and
a molding compound encapsulating the circuit substrate and the electronic component, wherein the molding compound directly touches the first region of the first boundary surface and the second insulation layer.

2. The electronic package module of claim 1, wherein the second insulation layer further comprising:
a plurality of trenches, wherein the molding compound directly touches inner surfaces of the plurality of trenches, and the plurality of trenches and the first region of the first boundary surface are not overlapping.

3. The electronic package module of claim 2, wherein the inner surfaces of the plurality of trenches comprise a part of the first boundary surface.

4. The electronic package module of claim 2, wherein the electronic component overlaps a second region of the first boundary surface surrounded by the first region, and at least one of the plurality of trenches is located between the second region and the first region.

5. The electronic package module of claim 2, wherein the electronic component covers at least one of the plurality of trenches.

6. The electronic package module of claim 2, wherein the electronic component covers none of the plurality of trenches.

7. The electronic package module of claim 4, further comprising:
a plurality of soldering materials electrically connecting the electronic component with the second circuit layer, and the plurality of soldering materials overlaps a plurality of third regions, wherein the plurality of third region is surrounded by the first region;
wherein at least one of the plurality of trenches is located between two of the plurality of third regions adjacent to each other.

8. The electronic package module of claim 1, further comprising:
a third circuit layer located on a second boundary surface of the second insulation layer and electrically connected to the second circuit layer, wherein the first boundary surface and the second boundary surface are located on two opposite sides of the second insulation layer separately; and
a third insulation layer located on the second boundary surface and partially covering the third circuit layer, wherein the third insulation layer bares a second region of the second boundary surface, and the second region is located on a perimeter of the second boundary surface;
wherein the molding compound directly touches the second region.

9. The electronic package module of claim 1, wherein the molding compound covers a side wall of the first insulation layer.

10. A method for fabricating an electronic package module, comprising:
providing a provisional carrier;
forming a circuit substrate on the provisional carrier and baring a surface of the provisional carrier;
disposing an electronic component on the circuit substrate and electrically connecting the electronic component with the circuit substrate;
disposing a molding compound on the provisional carrier, and the circuit substrate and the electronic component are encapsulated by the molding compound, wherein the molding compound covers the surface of the provisional carrier;
removing the provisional carrier after disposing the molding compound; and
cutting the molding compound after removing the provisional carrier;
wherein the circuit substrate comprises a recessed region surrounding a side wall of the circuit substrate, and the recessed region is filled up with the molding compound.

11. The method of claim 10, wherein forming the circuit substrate on the provisional carrier, comprising:
forming a first circuit layer on the provisional carrier;
disposing a first insulation material on the first circuit layer, so that the first insulation material covers the provisional carrier and the first circuit layer;
patterning the first insulation material to form a first insulation layer, and the first insulation layer bares the surface of the provisional carrier;
forming a second circuit layer on the first circuit layer, wherein the second circuit layer is electrically connected to the first circuit layer;
disposing a second insulation material on the second circuit layer, so that the second insulation material covers the first insulation layer and the second circuit layer;
patterning the second insulation material to form a second insulation layer, wherein a boundary surface of the first insulation layer is located between the first insulation layer and the second insulation layer, and the second insulation layer bares a region of the boundary surface, and thus the recessed region of the circuit substrate is formed.

12. The method of claim 11, wherein the side wall of the circuit substrate is the side wall of the second insulation layer, and the side wall is surrounded by the recessed region.

13. The method of claim 11, further comprising:
forming a surface treatment layer on the first circuit layer after removing the provisional carrier.

14. The method of claim 11, further comprising:
forming a surface treatment layer on the first circuit layer after cutting the molding compound.

15. The method of claim 11, further comprising:
electrically connecting the electronic component with the second circuit layer through a plurality of soldering materials, wherein the second insulation layer bares a part of the boundary surface, and thus a plurality of trenches spaced from the plurality of soldering materials and the recessed region are formed.
